(19) United States
(12) Patent Application Publication
(10) Pub. No.: US 2009/0002974 A1
(43) Pub. Date: Jan. 1, 2009

(54) Power Converter Unit

(75) Inventors: Koichi YAHATA, Hitachinaka-shi (JP); Yoshio Akaishi, Hitachinaka-shi (JP); Yuuki Takahashi, Hitachiota-shi (JP)

Correspondence Address: CROWELL & MORING LLP;INTELLECTUAL PROPERTY GROUP, P.O. BOX 14300, WASHINGTON, DC, 20044-4300, US

(73) Assignee: Hitachi, Ltd., Tokyo (JP)

(21) Appl. No.: 12/130,455

(22) Filed: May 30, 2008

(30) Foreign Application Priority Data
May 31, 2007 (JP) 2007-144346

(51) Int. Cl. H05K 7/04

(52) U.S. Cl. 361/820

(57) ABSTRACT

A power converter unit has a metal case; a power module having a plurality of power semiconductor devices that is provided inside the metal case; a gate drive circuit board having a circuit for driving the plurality of the power semiconductor devices that is mounted on the power module; a voltage sensor that is mounted on the gate drive circuit board; a metal plate for electrically connecting the metal case with the gate drive circuit board; screws and soldered parts for fixing the metal plate to the gate drive circuit board; a first wiring that is set up on the gate drive circuit board for electrically connecting the voltage sensor with the soldered parts; and a second wiring that is set up on the gate drive circuit board for electrically connecting the screws and the soldered parts.

### INCORPORATION BY REFERENCE

The disclosure of the following priority application is herein incorporated by reference:

Japanese Patent Application No. 2007-144346 filed May 31, 2007

### BACKGROUND OF THE INVENTION

1. Field of the Invention

The present invention relates to a power converter unit, in particular a power converter unit having a voltage sensor.

2. Description of Related Art

A high-voltage line (a positive and negative power line that is supplied from a battery) that is applied on an inverter unit needs to be electrically insulated from a metal case of the power converter unit. In the case where any abnormality causes insulation reduction between the high-voltage line and the metal case, this has to be detected. Therefore, in general, the power converter unit is provided with a leak detection circuit for detecting reduction of insulation between the high-voltage line and the metal case.

The leak detection circuit includes the voltage sensor. The voltage sensor measures voltage between the high-voltage line and the metal case of the power converter unit. Consequently, the voltage sensor and the metal case need to be connected with each other.

Conventionally, a soft wiring part such as lead wire is used for the connection. This wiring method, however, has a problem such as vibrating wiring makes the lead wire cut when the power converter unit vibrates heavily.

Japanese Laid Open Patent Publication No. 2000-285999 (Refer to patent document 1) discloses a method using a metal plate, as a substitute for wiring, which is fixed with screws to the object at one end of the metal plate, while fixed to a board at the other end through a thread provided on the metal plate, with the board sandwiched with the metal plate. Having a lead at the end of the metal plate and soldering the board leads to an electrical connection.

However, in the case where the power converter unit is used in an environment with a great temperature difference, solder fatigue caused by a temperature cycling may lead to a crack. This could result in a defective electrical connection.

The present invention intends to provide the power converter unit having a wiring structure for voltage sensor that is resistant against the vibration and the temperature difference.

### SUMMARY OF THE INVENTION

A power converter unit according to a first aspect of the present invention includes: a metal case; a power module, provided inside the metal case, that comprises a plurality of power semiconductor devices; a gate drive circuit board, mounted on the power module, that comprises a circuit for driving the plurality of the power semiconductor devices; a voltage sensor that is mounted on the gate drive circuit board; a metal plate that electrically connects the metal case with the gate drive circuit board; a first fixed part and a second fixed part that fix the metal plate to the gate drive circuit board; a first wiring, provided on the gate drive circuit board, that electrically connects the voltage sensor with the second fixed part; and a second wiring, provided on the gate drive circuit board, that electrically connects the first fixed part with the second fixed part.

A power converter unit according to a second aspect of the present invention includes: a metal case; a power module, provided inside the metal case, that comprises a plurality of power semiconductor devices; a gate drive circuit board, mounted on the power module, that comprises a circuit for driving the plurality of the power semiconductor devices; a shield plate that is fixed to the metal case and placed between the power module and the gate drive circuit board; a voltage sensor that is disposed on the gate drive circuit board; a protrusion that is extended from the shield plate; a first fixed part that fixes the shield plate to the gate drive circuit board; a second fixed part that fixes the protrusion to the gate drive circuit board; and a wiring that is provided on the gate drive circuit board to electrically connect the voltage sensor with the first fixed part.

A reliable power converter unit can be provided in accordance with the present invention.

### BRIEF DESCRIPTION OF THE DRAWINGS

FIG. 1 is a block diagram of vehicle in accordance with an embodiment of the present invention.

FIG. 2 is a circuit diagram of the power converter unit in accordance with the embodiment of the present invention.

FIG. 3 is a perspective view of the power converter unit in accordance with the embodiment of the present invention.

FIG. 4 is an exploded perspective view of the power converter unit in accordance with the embodiment of the present invention.

FIG. 5 is a perspective view of a power module in accordance with the embodiment of the present invention.

FIG. 6 is a plan view that illustrates a first embodiment of the present invention.

FIG. 7 is a side view that illustrates the first embodiment of the present invention.

FIG. 8 is a cross-sectional view that illustrates the first embodiment of the present invention.

FIG. 9 is a diagram that illustrates a second embodiment of the present invention.

FIG. 10 is a plan view that illustrates a third embodiment of the present invention.

FIG. 11 is a side view that illustrates the third embodiment of the present invention.

FIG. 12 is across-sectional view that illustrates the third embodiment of the present invention.

### DESCRIPTION OF PREFERRED EMBODIMENTS

### The First Embodiment

First Embodiment of the present invention will be described in detail with reference to the drawings hereinafter.

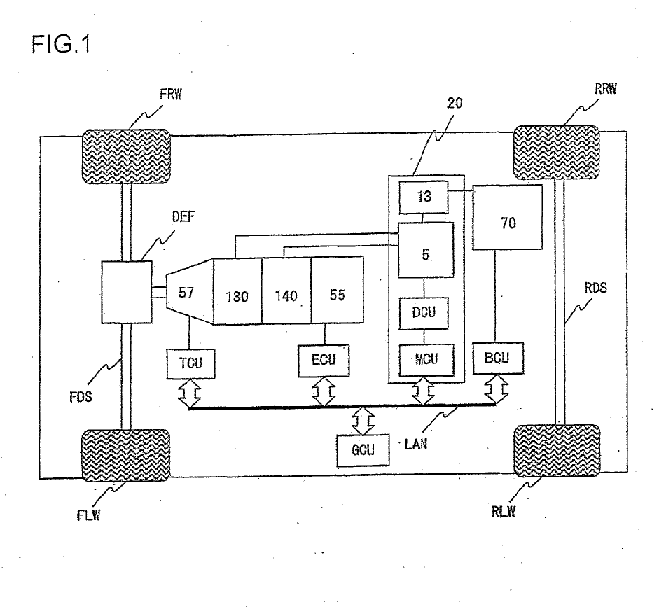

FIG. 1 is a block diagram of a hybrid electric vehicle (hereinafter referred to as “HEV”) that is produced by combination of an in-vehicle electrical system configured with a power converter unit 20 in accordance with an embodiment of the present invention and an internal combustion engine system.

The HEV in accordance with the embodiment includes front wheels FRW and FLW, rear wheels RRW and RLW, a front drive shaft FDS, a rear drive shaft RDS, a differential gear DEF, a transmission 57, an engine 55, electric rotating machines 130 and 140, the power converter unit 20, a battery 70, an engine control unit ECU, a transmission control unit TCU, a motor control unit MCU, a battery control unit BCU, and an in-vehicle local area network LAN.

In accordance with the embodiment, drive power is generated with the engine 55 and the two electric rotating machines 130 and 140, and transmitted to the front wheels FRW and FLW through the transmission 57, the differential gear DEF, and the front drive shaft FDS.

The transmission 57 is a device that is made up with a plurality of gears and changes gear ratio in response to an operational status such as speed.

The differential gear DEF is a device that transfers the power properly to the right wheel FRW and the left wheel FLW in response to a speed difference between them on curve, etc.

The engine 55 is composed of a plurality of components such as an injector, a throttle valve, an ignition, intake and exhaust valves, etc (all of them are not figured herein). The injector is a fuel injection valve that controls the fuel that is to be injected into cylinders of the engine 55. The throttle valve is a restrictor that controls air mass that is to be supplied into the cylinders of the engine 55. The ignition is a fire source that combusts a fuel-air mixture in the cylinders of the engine 55. The intake and exhaust valves are valves that are provided for the intake and exhaust in the cylinders of the engine 55.

Each of the electric rotating machines 130 and 140 is a three-phase alternating current synchronous electric rotating machine, that is, a permanent magnet electric rotating machine. And, a three-phase alternating current induction electric rotating machine or a reluctance electric rotating machine may as well be used.

Each of the electric rotating machines 130 and 140 includes a rotor, which is to rotate, and a stator, which is to produce a rotating magnetic field.

The rotor includes either a plurality of permanent magnets that are put in a core or a plurality of permanent magnets that are arranged on an outer peripheral surface. The stator includes copper wire wound on a magnetic steel sheet.

Applying three-phase alternating current to a coil of the stator leads to generating the rotating magnetic field, and torque that is generated by the rotor leads to rotating the electric rotating machines 130 and 140.

The power converter unit 20 controls current for applying to the electric rotating machines 130 and 140 through switching operation of the power semiconductor devices. That is, the power semiconductor device 20 controls each of the electric rotating machines 130 and 140 by applying direct current electricity from the battery 70 to the electric rotating machines 130 and 140 (ON), or stopping applying (OFF) the same. In accordance with the embodiment, since each of the electric rotating machines 130 and 140 is three-phase alternating current rotating machine, duty cycle of ON/OFF switching causes three-phase alternating current voltage to be generated, and causes drive power of the electric rotating machines 130 and 140 to be controlled (Pulse Width Modulation Control).

The power converter unit 20 is made up with a capacitor module 13 that supplies electric power upon switching, a power module 5 for switching, a drive circuit unit DCU for driving the power module 5, and the motor control unit MCU for determining the duty cycle of switching.

The motor control unit MCU controls the switching operation of the power module 5 for driving the electric rotating machines 130 and 140 in response to a command for rotational speed n* and a torque command value τ* from a general control unit GCU. For this purpose, the motor control unit MCU is loaded with a microcomputer for necessary calculation and a memory for storing such as a data map.

The drive circuit unit DCU drives the power module 5 according to a PWM signal that is determined at the motor control unit MCU. For this purpose, the drive circuit unit DCU is loaded with a circuit having a drive capability of several amperes and several tens of volts, which is necessary for driving the power module 5. And, the drive circuit unit DCU is loaded with a circuit that insulates control signals, for the purpose of driving power semiconductor devices of the high-potential side.

The battery 70, which is a direct-current power supply, includes a secondary battery with high power density such as a nickel metal hydride battery or a lithium-ion battery. The battery 70 supplies the electric power to the electric rotating machines 130 and 140 through the power converter unit 20. Or, conversely, the battery 70 stores the electric power that is generated with the electric rotating machines 130 and 140 and converted with the power converter unit 20.

The transmission 57, the engine 55, the power converter unit 20, and the battery 70 are controlled by the transmission control unit TCU, the engine control unit ECU, the motor control unit MCU, and the battery control unit BCU, respectively. These control units are connected to the general control unit GCU with the in-vehicle local area network LAN, controlled according to the command value designated by the general control unit GCU, and allowed to perform two-way communication with the general control unit GCU. Each control unit controls the devices according to the command signal (command value) from the general control unit GCU, output signals (a variety of parameter values) from a variety of sensors, and other control units, data or maps that are stored in a storage unit in advance, etc.

The general control unit GCU, for example, calculates a necessary torque value of the vehicle according to the driver's pressing the accelerator based on his/her acceleration intention. The necessary torque value is distributed to an output torque value of the engine 55 and an output torque value of the first electric rotating machine 130 for better driving efficiency of the engine 55. The output torque value of the engine 55 is transmitted to the engine control unit ECU as an engine torque command signal. On the other hand, the output torque value of the first electric rotating machine 130 is transmitted to the motor control unit MCU as a motor torque command signal. The engine torque command signal controls the engine 55, meanwhile the motor torque command signal controls the electric rotating machine 130.

A driving mode for the hybrid vehicle will be described hereinafter.

At startup and during low-speed running of the vehicle, the electric rotating machine 130 is mainly operated, and rotary drive power that is generated in the electric rotating machine 130 is transmitted to the front drive shaft FDS through the transmission 57 and the differential gear DEF. This causes the front drive shaft FDS to be rotary-driven by the rotary drive power of the electric rotating machine 130. Subsequently, the front wheels FRW and FLW are rotary-driven, and the vehicle moves. At this time, the output electrical power (direct current power) from the battery 70 is converted to three-phase alternating current electrical power by the power converter unit 20, and supplied to the electric rotating machine 130.

During normal running (medium-speed and high-speed running) of the vehicle, rotary drive power generated in the engine 55 and rotary drive power generated in the electric rotating machine 130 are transmitted to the front drive shaft FDS through the transmission 57 and the differential gear DEF, using both the engine 55 and the electric rotating machine 130 at the same time. This causes the front drive shaft FDS to be rotary-driven by the rotary drive power of both the engine 55 and the electric rotating machine 130. Subsequently, the front wheels FRW and FLW are rotary-driven, and the vehicle moves. A part of the rotary drive power generated in the engine 55 is supplied to the electric rotating machine 140. This power distribution causes the electric rotating machine 140 to be rotary-driven by the part of the rotary drive power generated in the engine 55, and to be operated as a generator to generate electric power. Three-phase alternating current electrical power generated by the electric rotating machine 140 is supplied to the power converter unit 20, rectified into direct current power temporarily, converted into three-phase alternating current electrical power, and then supplied to the electric rotating machine 130. This enables the electric rotating machine 130 to generate a rotary drive power.

During accelerating the speed of the vehicle, particularly accelerating rapidly with the throttle valve, which controls air mass that is to be provided for the engine 55, open full (for example, when climbing a steep slope where the degree of driver's pressing an accelerator pedal is great), in addition to the operation for the normal running, the output electrical power from the battery 70 is converted into the three-phase alternating current electrical power by the power converter unit 20 and supplied to the electric rotating machine 130. Thus, the rotary drive power generated by the electric rotating machine 130 increases.

During slowing down and braking of the vehicle, the rotary drive power of the front drive shaft FDS made by rotation of the front wheels FRW and FLW is supplied to the electric rotating machine 130 through the differential gear DEF and the transmission 57 and the electric rotating machine 130 is operated as a generator to generate electric power. The three-phase alternating current electrical power generated by the electric power generation (regenerative energy) is rectified into direct current power by the power converter unit 20 and supplied to the battery 70. This allows the battery 70 to be charged.

When the vehicle is stopping, the drive of the engine 55 and the electric rotating machines 130 and 140 basically stop. If the charge of the battery 70 is low, the engine 55 is driven to operate the electric rotating machine 140 as a generator. And the generated electrical power is charged in the battery 70 through the power converter unit 20.

The electric rotating machines 130 and 140 are not limited to perform generating electric power and driving in the above mentioned way: actually, the electric rotating machines 130 and 140 may perform generating electric power and driving the other way around depending upon the efficiency.

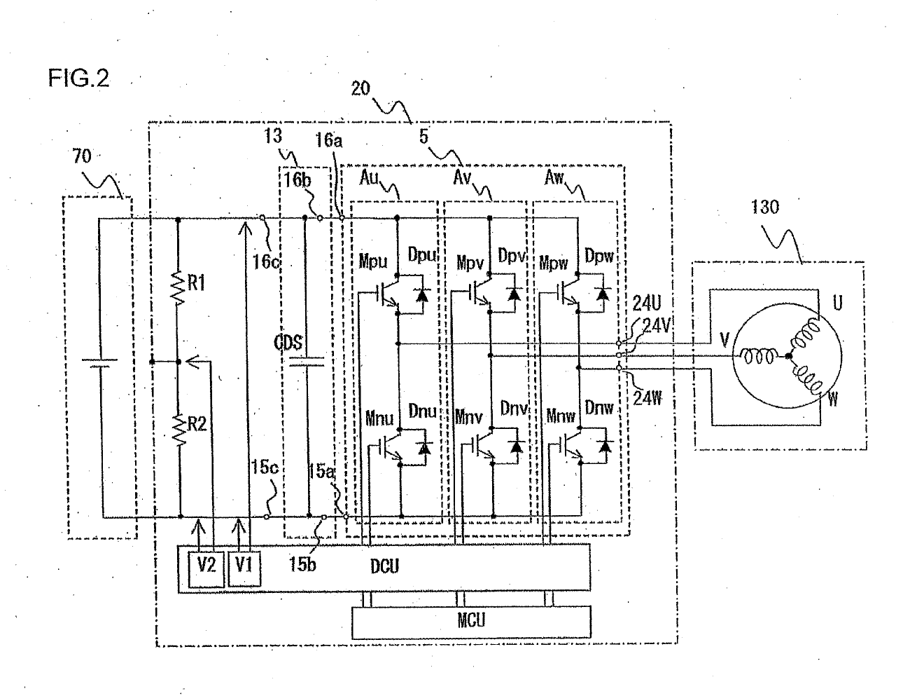

FIG. 2 is the circuit diagram of a main circuit of the power converter unit 20 in accordance with the embodiment of the present invention.

The power converter unit 20 in accordance with the embodiment is made up with the capacitor module 13 that supplies electric power upon switching, the power module 5 for switching operation, the drive circuit unit DCU that supplies switching electric power for the power module 5, and the motor control unit MCU that controls the switching operation of the power module 5 for controlling the electric rotating machines.

FIG. 2 shows a configuration of the power converter unit 20 only for the first electric rotating machine 130; however, the power converter unit 20 shown in FIG. 1 includes the power module 5 and the drive circuit unit DCU also for the second electric rotating machine 140, with the same configuration as shown in FIG. 2.

The power module 5 is made up with three bridge circuits (Au, Av, Aw) for three-phase alternating current output, using the power semiconductor devices M (Mpu, Mnu, Mpv, Mnv, Mpw, Mnw) that perform switching operation of ON/OFF.

Both ends of the bridge circuits are connected to connecting terminals 15b and 16b of the capacitor module 13 through a connecting terminal 15a and a connecting terminal 16a. The capacitor module 13 is connected to the battery 70 through connecting terminals 15c and 16c.

Each midpoint of the bridge circuits is connected to three-phase input connecting terminals of the electric rotating machine 130 (U connecting terminal, V connecting terminal, W connecting terminal, respectively) through connecting terminals 24U, 24V, and 24W, respectively. The bridge circuit is also known as an arm: the power semiconductor devices that are connected to the high-potential side are called upper arms; while, the power semiconductor devices that are connected to the low-potential side are called lower arms.

The power semiconductor devices having the three bridge circuits (Au, Av, Aw) perform switching operations of ON/OFF with a phase difference of 120° and switch the connections of the high-potential side (the upper arm) and the low-potential side (the lower arm), so as to generate three-phase alternating current voltage. Thus, three-phase alternating current voltage of pulse voltage waveform with duty cycle is generated.

Since the power semiconductor devices M (Mpu, Mnu, Mpv, Mnv, Mpw, Mnw) perform switching with large current, a drive circuit is necessary for driving the power semiconductor devices. For this purpose, the drive circuit unit DCU is connected with the power module 5 for driving the power semiconductor devices.

The motor control unit MCU is connected with the drive circuit unit DCU. The drive circuit unit DCU receives each of signals of switching cycle and timing (duty cycle of pulse voltage) according to rotational speed and torque of the electric rotating machines from the motor control unit MCU.

In accordance with the embodiment, an IGBT (insulated gate bipolar transistor) is employed for the power semiconductor devices M (Mpu, Mnu, Mpv, Mnv, Mpw, Mnw). Therefore, diodes D (Dpu, Dnu, Dpv, Dnv, Dpw, Dnw) for reversing current at switching are connected externally to the IGBTs in antiparallel.

In accordance with the embodiment, each of the power semiconductor devices M of the upper or lower arm of each phase is composed of one component (two components when the diode is counted in). The power semiconductor devices M may as well be connected in parallel in accordance with the ampacity.

In accordance with the embodiment, the IGBT (insulated gate bipolar transistor) is employed for the power semiconductor devices M. However, a MOSFET (metal-oxide semiconductor field-effect transistor) may as well be substituted for the IGBT. In the case of employing the MOSFET, a diode for reversing current does not need to be connected externally since the one is already incorporated in the MOSFET.

In accordance with the embodiment, the power converter unit 20 has a leak detection circuit that includes at least two voltage sensors. One voltage sensor is a voltage sensor (V1) for measuring voltage between the high-voltage lines, that is, the positive terminal (P) line and the negative terminal (N) line; the other voltage sensor is a voltage sensor (V2) for measuring voltage between the negative terminal (N) line, which is the high-voltage line, and a metal case of the power converter unit 20.

Instead of the two voltage sensors V1 and V2, one voltage sensor and a switch with a chip resistor, etc. may as well be employed. That is, switching one terminal of the voltage sensor between the positive terminal (P) line and the metal case using the switch allows the one voltage sensor to measure voltages at two points.

As shown in the embodiment, in the case where values of resistors R1 and R2, which are inserted in series in between the positive terminal (P) line and the negative terminal (N) line, are set to be the same as each other, voltage between the positive terminal (P) line and the metal case is half as much as that between the positive terminal (P) line and the negative terminal (N) line, with normal high-voltage insulation of the power converter unit 20; meanwhile, any abnormality may cause insulation deterioration between the positive terminal (P) line and the metal case, or between the negative terminal (N) line and the metal case. In this case, each voltage swings up and down, and the insulation deterioration is surely detectable.

In accordance with the embodiment, the values of resistors R1 and R2 are set to be same as each other; however, the values may as well be different from each other if necessary.

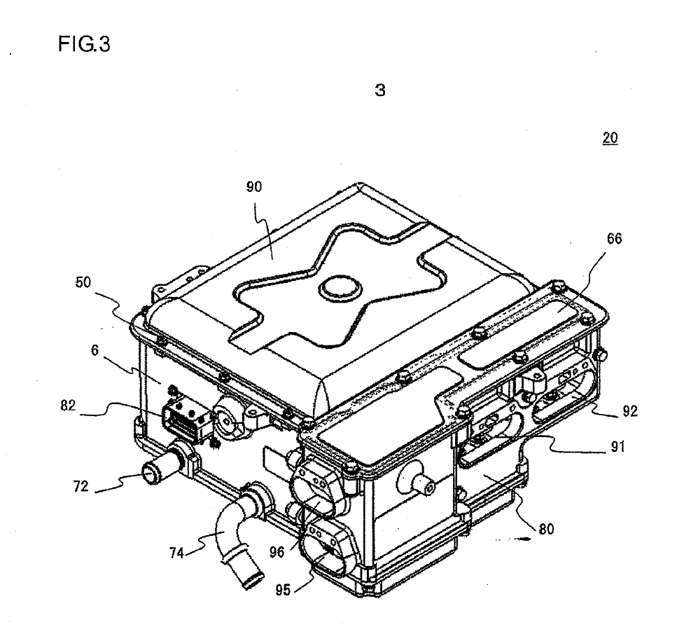

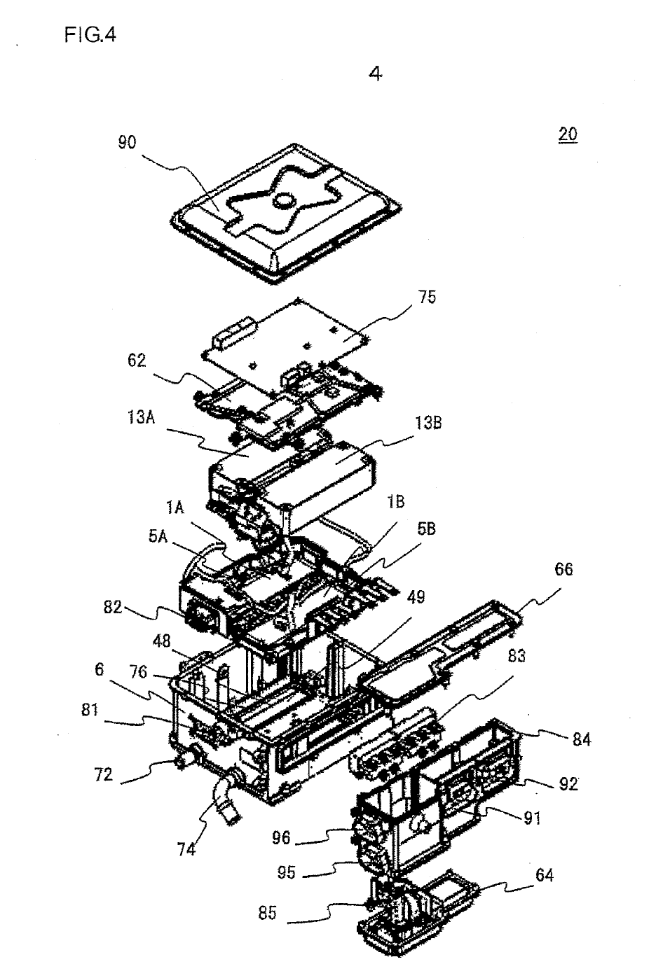

FIG. 3 is a perspective view of the power converter unit 20, and FIG. 4 is an exploded perspective view of the power converter unit 20 in accordance with the embodiment.

The power converter unit 20 has a metal case 4 that has a shape of a box. A waterway-forming object 48 in which a refrigerant path 76 where cooling water circulates is provided is equipped at the bottom of the metal case 4. An inlet pipe 72 and an outlet pipe 74 for supplying the cooling water to the refrigerant path 76 protrude outside at the bottom of the metal case 4. The waterway-forming object 48 is to create the refrigerant path. Engine cooling water is used as the refrigerant in accordance with the embodiment.

The power module 5 of the power converter unit 20 is made up with a first power module 5A and a second power module 5B that are placed in parallel with each other in the metal case 4. Each of the first power module 5A and the second power module 5B is equipped with cooling fins (not figured herein). On the other hand, the waterway-forming object 48 has openings 49. Fixing the first power module 5A and the second power module 5B to the waterway-forming object 48 causes the cooling fins to protrude into the refrigerant path 76 through the opening 49. The opening 49 is closed with a metal wall around the cooling fins so as to create the cooling waterway and so as not to leak the cooling water.

The first power module 5A and the second power module 5B are placed respectively on left and right of an imaginary line segment that is orthogonal to the sidewall where the inlet pipe 72 and the outlet pipe 74 are fixed to the metal case 4.

The cooling waterway that is formed in the waterway-forming object 48 extends from the inlet pipe 72 for the cooling water to the other end along a long side of the bottom of the metal case 4, makes a U-turn at the other end, and extends to the outlet pipe 74 along the long side of the bottom of the metal case 4. Two waterways in parallel with each other along the long side are formed in the waterway-forming object 48. The openings 49 which open to the waterways, are formed in the waterway-forming object 48. The first power module 5A and the second power module 5B are fixed in the waterway-forming object 48 along the above mentioned path.

The protrusion of the cooling fins of the first power module 5A and the second power module 5B into the waterway leads to an efficient cooling. As well as, radiator planes of the first power module 5A and the second power module 5B attaching firmly to the metallic waterway-forming object 48 leads to an efficient radiator configuration. Moreover, since the opening 49 is closed with the radiator planes of the first power module 5A and the second power module 5B, the structure becomes smaller and the cooling effect is improved.

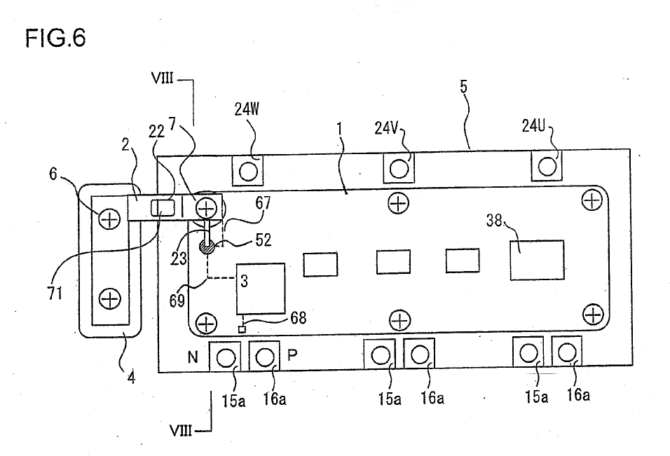

A first gate drive circuit board 1A and a second gate drive circuit board 2A are mounted respectively on the first power module 5A and the second power module 5B in parallel with each other. The first gate drive circuit board 1A and the second gate drive circuit board 2A constitute a gate drive circuit board 1 which is shown in FIG. 6.

The first gate drive circuit board 1A, which is mounted on the first power module 5A, is seen from plan view to be a little smaller than the first power module 5A. Likewise, the second gate drive circuit board 1B, which is mounted on the second power module 5B, is seen from plan view to be a little smaller than the second power module 5B.

The inlet pipe 72 and the outlet pipe 74 for the cooling water are configured on the side of the metal case 4. Furthermore, a hole 81 is cut on the same side and a signal connector 82 is disposed in the hole 81.

The capacitor module 13 having a plurality of smoothing capacitors is mounted on the first gate drive circuit board 1A and the second gate drive circuit board 2A. The capacitor module 13 has a first capacitor module 13A and a second capacitor module 13B. The first capacitor module 13A and the second capacitor module 13B are mounted respectively on the first gate drive circuit board 1A and the second gate drive circuit board 2A.

A flat holding board 62 is fixed and mounted on the first capacitor module 13A and the second capacitor module 13B, with each of its sides attaching firmly to inner walls of the metal case 4. The holding board 62 supports the first capacitor module 13A and the second capacitor module 13B on the surface of the power module side, at the same time, holds and fixes an electric rotating machine control circuit board 75 on the surface of the other side. The holding board 62, which is composed of metallic material, allows heat generated in the first capacitor module 13A and the second capacitor module 13B and the control circuit board 75, which mounts the motor control unit MCU, to be radiated to the metal case 4.

As described above, the power module 5, the gate drive circuit board 1, the capacitor module 13, the holding board 62, the control circuit board 75 are housed in the metal case 4. An upper opening of the metal case 4 is covered with a metallic cover 90. The metallic cover 90 is fixated to the metal case 4 using screws 50.

A connector box 80 is placed on a sidewall of the metal case 4, which is located at a side of the wall, that is, a front wall, where inlet pipe 72 and the outlet pipe 74 are configured. The connector box 80 has direct current connectors 95 and 96 with which the direct current from the battery 70 is supplied to the connecting terminals 15c and 16b of the capacitor module 13; a terminal block 85 for direct current configured inside the direct current connectors 95 and 96; alternating current connectors 91 and 92 for connecting to the first electric rotating machine 130 and the second electric rotating machine 140; and, a terminal block 83 for alternating current disposed inside the alternating current connectors 91 and 92.

The terminal block 85 for direct current is electrically connected to electrodes of the first capacitor module 13A and the second capacitor module 13B through a bus bar. On the other hand, the terminal block 83 for alternating current is electrically connected to each of the terminals of the plurality of the power modules 5A and 5B, which constitute the power module 5, through a bus bar.

The connector box 80 is composed of a body 84 attached with a bottom plate 64 on which the terminal block 85 for direct current is mounted and a cover 66. This makes the construction of the connector box 80 easy.

The above described configuration realizes the power converter unit 20 small in size.

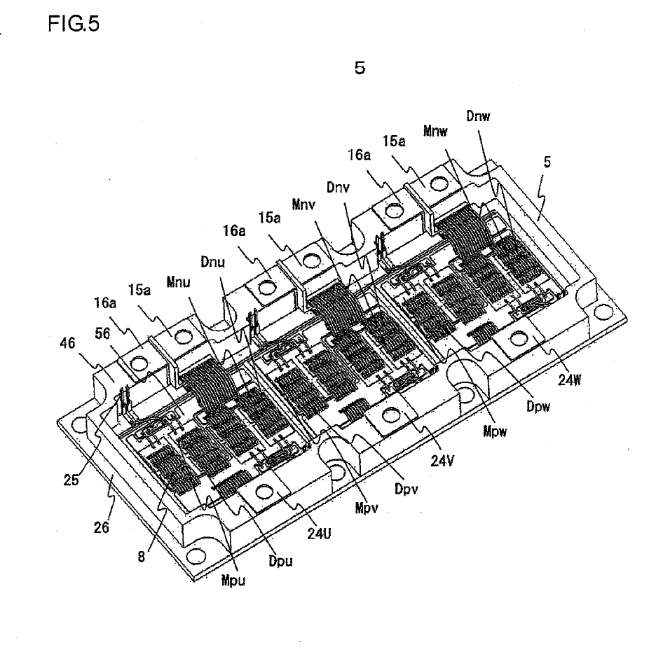

FIG. 5 is a perspective view of the power module 5 in accordance with the embodiment.

The power module 5 has the plurality of the power semiconductor devices M (Mpu, Mnu, Mpv, Mnv, Mpw, Mnw). The diodes D (Dpu, Dnu, Dpv, Dnv, Dpw, Dnw) for reversing current are arranged in parallel with the power semiconductor devices M. In accordance with the embodiment, each of the power semiconductor devices M and each of the diodes D are connected in parallel with each other to make up each of the components on the circuit. However, the number of the devices is modifiable in accordance with a specification, etc.

The connecting terminals connected to the capacitor module 13 are set up along the long sides of the power module 5. The plurality of the connecting terminals 16a of the positive terminal side and the connecting terminals 15a of the negative terminal side are set up in a row on one long side. The connecting terminals 24U, 24V, and 24W, which output the alternate current for driving the electric rotating machine 130, are set up in a row on the other long side. Outputting three-phase alternating current, which are U phase, V phase, and W phase, from the connecting terminals 24U, 24V, and 24W, respectively causes the drive control of the electric rotating machine 130. The power semiconductor devices M, the diodes D, and each of the connecting terminals are electrically connected to each other using aluminum wire 8.

A gate pin 25 is set up in the power module 5 for transmitting control signals (gate signals) supplied from the gate drive circuit board 1 to the gate terminals of the power semiconductor devices M (Mpu, Mnu, Mpv, Mnv, Mpw, Mnw). The power semiconductor devices M are controlled in response to the gate signals from the gate drive circuit board 1. Six sets of the power semiconductor devices M are provided; therefore, six sets of the gate pins, each of which is to be connected to each of the power semiconductor devices M, are set up.

The power semiconductor devices M and the diodes D are mounted on an insulating substrate 56 formed of aluminum nitride (AlN), etc. Aluminum nitride (AlN) is widely used due to its high thermal conductivity. Silicon nitride (SiN) may as well be substituted for aluminum nitride (AlN). Employing silicon nitride (SiN) allows the insulating substrate 56 to be formed thin due to its high toughness.

The insulating substrate 56 has a pattern formed with nickel-plated copper, etc. on either entire or part of a side facing a metal base 26; on the other hand, a wiring pattern is formed with nickel-plated copper, etc. on a side on which the power semiconductor devices M, etc. are mounted. Applying metal on both sides of the insulating substrate 56 enables the power semiconductor devices M, etc. to be soldered to the metal base 26, and enables a sandwich structure where the insulating substrate 56 is sandwiched with metal. This structure prevents deformation resulted from difference in coefficient of thermal expansion upon temperature change.

Employing the sandwich structure results in, with the insulating substrate 56 thin, an increase in eddy current that is induced by the entire pattern on the side facing the metal base 26, in response to current change in the wiring pattern on the side on which the power semiconductor devices M are mounted, upon switching the power semiconductor devices M. This results in reducing parasitic inductance of the wiring pattern on the insulating substrate 56, and contributing to realizing low inductance in the power module 5.

The metal base 26 formed with copper, etc. is placed underneath the power module 5. The cooling fins in the shape of linear or pin (not figured herein) are configured underneath the metal base 26. Mounting the power module 5 in the metal case 4 causes the refrigerant path to be formed. The cooling water runs under the metal base 26.

Connecting configuration of the voltage sensor of the present invention will be described hereinafter with reference to a plurality of examples of embodiments.

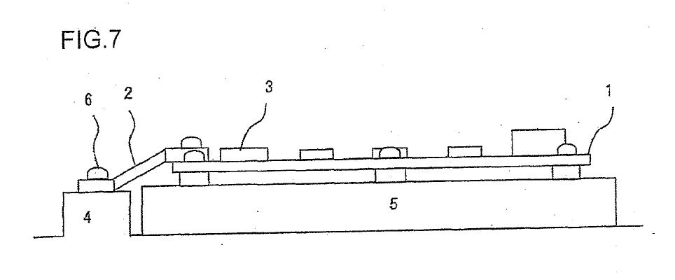

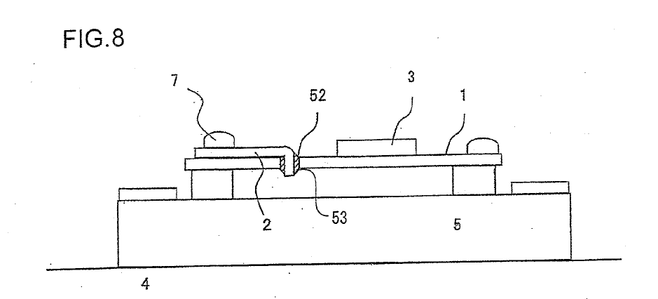

FIG. 6 to FIG. 8 are structure diagrams in accordance with the first embodiment. FIG. 6 is a plan view in accordance with the first embodiment. FIG. 7 is the side view in accordance with the first embodiment. FIG. 8 is the cross-sectional view between VIII and VIII of FIG. 6.

In these drawings, 5 represents the power module; 1 represents the gate drive circuit board; 3 represents the voltage sensor that is mounted on the gate drive circuit board 1; and, 4 represents the metal case of the power converter unit 20 on which the power module 5 is mounted. The power module 5 is fixated to the metal case 4 with screws 6. 2 represents a metal plate that connects the metal case 4 with the voltage sensor on the gate drive circuit board 1. The metal plate 2 is tin-plated.

The gate drive circuit board 1 is composed of a printed circuit board on which the voltage sensor 3 and electronic components 38, which include a driver IC that drives the power module 5, etc., are mounted. A variety of circuits and the variety of the electronic components 38, which are mounted on the gate drive circuit board 1, constitute the drive circuit unit DCU.

In accordance with the embodiment, the voltage sensor 3 is the voltage sensor (V2) for measuring the voltage between the negative terminal (N) line, which is the high-voltage line, and the metal case 4 of the power converter unit 20. However, the voltage sensor 3 may as well be a voltage sensor that switches measuring either the voltage between the positive terminal (P) line and the negative terminal (N) line, or the voltage between the negative terminal (N) and the metal case 4, using the switch. That is to say, the voltage sensor 3 needs to be capable of measuring the voltage between the negative terminal (N) and the metal case 4.

In general, since the voltage sensor 3, which detects the high-voltage, has to be insulated from light electrical system such as control unit, etc, therefore the voltage sensor 3 is mounted on the gate drive circuit board 1 which is mounted on the power module 5.

Some terminals are configured on the power module 5 as part of a plurality of control pins, in order to connect between the positive terminal (P) line and the negative terminal (N) line. These terminals are electrically connected to each of the positive terminal (P) line and the negative terminal (N) line. Consequently, the voltage between the positive terminal (P) line and the negative terminal (N) line is measurable using wiring for connecting between these terminals.

On the other hand, the gate drive circuit board 1 and the metal case 4 of the power converter unit 20 have to be electrically connected to each other for measuring the voltage between the negative terminal (N) line and the metal case 4. For this reason, the gate drive circuit board 1 and the metal case 4 are electrically connected to each other using the metal plate 2 in accordance with the embodiment.

A terminal at one end of the voltage sensor 3 is electrically connected to one of the plurality of control pins set up on the power module 5 (not figured herein), through a wiring 68 that is provided on the gate drive circuit board 1. This control pin is electrically connected to the negative terminal (N) line.

On the other hand, a terminal at the other end of the voltage sensor 3 is electrically connected to the metal case 4 of the power converter unit 20, through a wiring 69 that is provided on the gate drive circuit board 1 and the metal plate 2. The connection between the metal plate 2 and the metal case 4 is fixated with the screws 6. Two screws 6 are employed for fixation in accordance with the embodiment. However, the number of screws is modifiable if necessary.

On the other hand, the connection between the gate drive circuit board 1 and the metal plate 2 on the power module 5 is achieved by double fixing using a screw 7.

The metal plate 2 is made up with a body 22, which is fixated with each of the metal case 4 and the gate drive circuit board 1 respectively using the screws 6 and the screw 7, and a lead 23, which extends from a part at which the body 22 is fixated with the screw 7 to the direction of its end. As shown in FIG. 8, the lead 23, which is narrow and extended from the metal plate 2, is bent downward at its end. And, its end is inserted into a through hole 53 which is made on the gate drive circuit board 1. At the through hole 53, the end of the lead 23 and the wiring 69 on the gate drive circuit board 1 are electrically connected to each other using a solder 52.

Thus, the wiring 69, which is electrically connected to the terminal at the one end of the voltage sensor 3, and the metal plate 2 are fixated using the screw 7 and the solder 52, which is provided in the through hole 53. Since the metal plate 2 is connected double using the screw 7 and the solder 52, secured fixing and high reliability of the electrical connection are realized.

In accordance with the above configuration, in the case where a strong vibration is applied on the power converter unit 20, a disconnection of the metal plate 2, which connects between the metal case 4 and the gate drive circuit board 1, that is caused by the strong vibration is effectively preventable. Even in the case where the screw 7 is loosened due to a vibration or a vertical contraction of a printed circuit board, too, since the lead 23 of the metal plate 2 is firmly connected to the gate drive circuit board 1 using the solder 52, a disconnection of the metal plate 2, which connects between the metal case 4 and the gate drive circuit board 1, is preventable.

In accordance with the embodiment, a wiring 67 is provided on the gate drive circuit board 1 in order to electrically connect between the connection through the solder 52 and the body 22 of the metal plate 2 that is fixated using the screw 7. The wiring 67 is configured electrically in parallel with the lead 23, which electrically connects between the screw 7 and the solder 52.

In accordance with the above configuration, even in the case where the soldered part of the lead 23 cracks due to thermal stress by a temperature cycling, etc., and the electrical connection of the lead 23 is defective, measuring the voltage between the negative terminal (N) line and the metal case 4 is carried on using the voltage sensor 3. This is because the other wiring 67, which is connected to the voltage sensor 3, is set up at the fixed part of the screw 7, hence the electrical connection between the metal case 4 and the voltage sensor 3 is prevented from being disconnected. This results in providing the power converter unit with high reliability.

The width of the lead 23 is made narrower than that of the body 22 in an effort of an easy soldering. If the width of the lead 23, which is connected with the gate drive circuit board 1 using the solder 52, is broadened, the thermal diffusion of the soldering makes the soldering difficult.

The lead 23, which extends from the body 22 to the end, is made relatively larger in length for a similar reason. Consequently, the length of the lead 23 of a first direction, which extends from the body 22 to the end, is preferred to be larger than that of the width of the body 22 (the same direction as the first direction).

The body 22 has a hole 71 in order to prevent the heat of soldering from being transferred to the metal case 4 through the body 22 of the metal plate 2. Having the hole 71, which narrows an effective width of the body 22, prevents the heat from being transferred. As a result, soldering is made so easier that connecting using solder is ensured.

The hole 71 is created on the body 22 in accordance with the embodiment. However, any other configuration which prevents heat from being transferred is applicable. The width of the body 22 is allowed to be partly narrow; for example, the width of the body 22 is allowed to be narrower in its middle part than that of the fixed part using the screw 7.

As illustrated in FIG. 7, since there is a gap between the height of the fixed part using the screws 6 on the metal case 4 and the height of the fixed part using the screw 7 on the gate drive circuit board 1, an inclination is configured in the body 22 of the metal plate 2 so as to bridge the gap.

### The Second Embodiment

The second embodiment of the present invention will be described hereinafter.

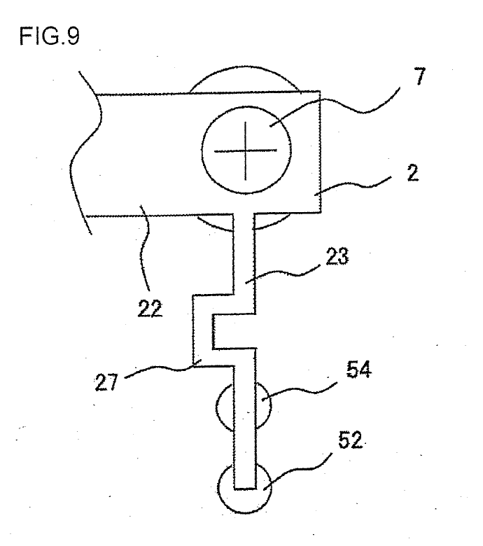

FIG. 9 is a diagram that illustrates a feature of the embodiment. This figure includes a detailed illustration for the metal plate 2, which electrically connects between the metal case 4 and the voltage sensor 3.

The metal plate 2 in accordance with the embodiment has a bend structure 27 in the lead 23 that is formed at the end of the metal plate 2. In other words, the lead 23 in accordance with the embodiment extends linearly from the body 22 to the solder 52 having four bent parts in between. Having the bend structure 27 is distinguished from the configuration in which the lead 23 extends only linearly from the body 22 to the solder 52 as in accordance with the first embodiment.

In accordance with the above-described configuration of the embodiment, mechanical stress is absorbed in the bending structure 27, even in the case where the solders 52 and 54 might crack due to expansion and contraction of the lead 23 which are resulted from change in temperature. In other words, the bend structure 27 allows the lead 23 to have two parts from which the lead 23 extends in a second direction which is perpendicular to the first direction in which the lead 23 extends from the body 22 to the end. Thus, the mechanical stress of the first direction is absorbed in the lead 23, which is bent and extends in the second direction. As a result, the crack in the solders 52 and 54 is effectively preventable, and hence the power converter unit 20 with high reliability is realized.

In accordance with the embodiment, the lead 23 is soldered at two parts: the solder 52 at the end, and the solder 54 in between the bent parts and the end. Having the soldering not only at the end of the lead 23 but also in between the end and the body 22 is distinguished from the configuration in accordance with the first embodiment.

The gate drive circuit board 1 has the through hole 53 at which the solder 52 is provided as in accordance with the first embodiment. The end of the lead 23 is inserted into the through hole 53, and electrically connected using the solder 52. On the other hand, the gate drive circuit board 1 has no through hole where the solder 54 is provided in between. The gate drive circuit board 1 and the lead 23 are connected with each other using the solder 54 on the gate drive circuit board 1. The gate drive circuit board 1 may as well be configured to have a through hole at the part where the solder 54 is.

In accordance with the above-described configuration of the embodiment, having the solders 52 and 54 at two parts, that is, the end and in between, results in reduction of the disconnection in the soldering caused by a crack in solder.

In accordance with the embodiment, two parts are soldered; however, three or more parts may as well be soldered.

The solder 54, which is provided in between, is more preferred to be configured close to the end of the lead 23. This is because having solder close to the body 22, which has broad width, causes heat of soldering to be easily transferred to the body 22, and the soldering is made difficult. In concrete terms, the solder 54 is preferred to be configured in between the bent part and the end. However, soldering may as well be made close to the body 22, such as in between the body 22 and the bent part, in the case where no particular difficulty exists in soldering.

### The Third Embodiment

The third embodiment of the present invention will be described hereinafter.

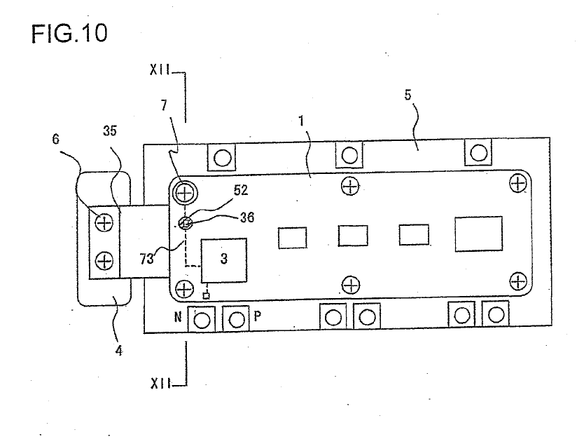

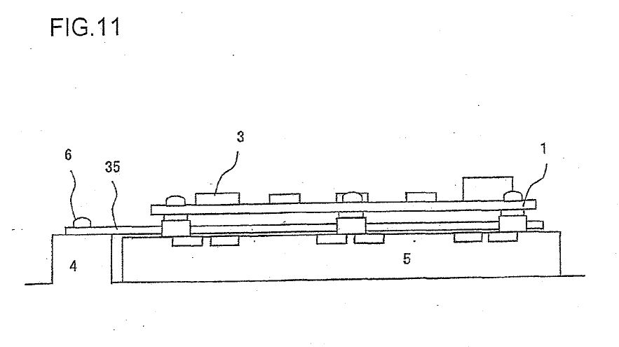

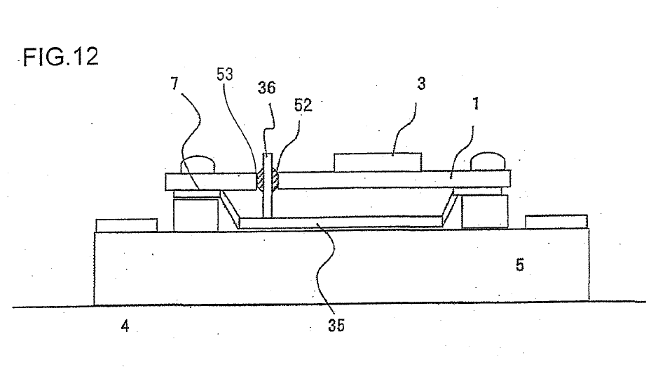

FIG. 10 to FIG. 12 are structure diagrams which illustrate the third embodiment. FIG. 10 is a plan view in accordance with the third embodiment. FIG. 11 is a side view in accordance with the third embodiment. FIG. 12 is a cross-sectional view between XII and XII of FIG. 10. Since the configuration is basically the same as that in accordance with the first embodiment, what are the same as the first embodiment will be skipped, and only what are different from the first embodiment will be described hereinafter.

In these drawings, 35 represents a shield plate that connects the metal case 4 with the voltage sensor 3 on the gate drive circuit board 1. The shield plate 35 is provided for reducing electromagnetic noise that is radiated from the power module 5 to the gate drive circuit board 1.

As illustrated in these drawings, the shield plate 35 is configured between the power module 5 and the gate drive circuit board 1. A peripheral part of the shield plate 35 is placed between the power module 5 and the gate drive circuit board 1, and is fixated to the power module 5 through the screw 7 and the gate drive circuit board 1.

The shield plate 35 has a protrusion 36. The protrusion 36 extends in a perpendicular direction to a flat surface of the shield plate 35, and penetrates the through hole 53 of the gate drive circuit board 1. The protrusion 36, which penetrates the through hole 53, is fixed using the solder 52 at the through hole 53. The protrusion 36 is integrated with the shield plate 35; however, the protrusion 36 may as well not be integrated with the shield plate 35.

The shield plate 35 is fixated to the metal case 4 using the screws 6, and fixated to the gate drive circuit board and power module 5 using the screw 7 and the solder 52. Thus, the shield plate 35, the gate drive circuit board 1 and the power module 5 are fixated double using the screw 7 and the solder 52. Therefore, secured fixing and high reliability of the electrical connection are realized.

In accordance with the above configuration, in the case where a strong vibration is applied on the power converter unit 20, a disconnection of the shield plate 35, which connects between the metal case 4 and the gate drive circuit board 1, that is caused by the strong vibration is effectively preventable. Even in the case where the screw 7 is loosened due to a vibration or a vertical contraction of a printed circuit board, too, since the protrusion 36 of the shield plate 35 is firmly connected to the gate drive circuit board 1 using the solder 52, a disconnection of the shield plate 35, which connects between the metal case 4 and the gate drive circuit board 1, is preventable.

In accordance with the embodiment, a wiring 73 is provided on the gate drive circuit board 1 in order to electrically connect between the voltage sensor 3 and the screw 7. The wiring 73 is configured electrically in parallel with the protrusion 36, which electrically connects between the screw 7 and the solder 52.

In accordance with the above configuration, even in the case where the soldered part of the protrusion 36 cracks due to thermal stress by a temperature cycling, etc., and the electrical connection is defective, measuring the voltage between the negative terminal (N) line and the metal case 4 is carried on using the voltage sensor 3. This is because the other wiring 73, which is connected to the voltage sensor 3, exists at the fixed part of the screw 7, hence the electrical connection between the metal case 4 and the voltage sensor 3 is prevented from being disconnected. This results in providing the power converter unit with high reliability.

As heretofore described, in accordance with the above embodiments, the power converter unit 20 having the wiring structure for the voltage sensor 3 with a simple configuration, resistance to vibration as well as resistance to temperature cycling, is provided. This results in providing the power converter unit 20 with high reliability.

The above-described embodiments are examples, and various modifications can be made without departing from the scope of the invention.

What is claimed is:

1. A power converter unit, comprising:
a metal case;
a power module, provided inside the metal case, that comprises a plurality of power semiconductor devices;
a gate drive circuit board, mounted on the power module, that comprises a circuit for driving the plurality of the power semiconductor devices;
a voltage sensor that is mounted on the gate drive circuit board;
a metal plate that electrically connects the metal case with the gate drive circuit board;
a first fixed part and a second fixed part that fix the metal plate to the gate drive circuit board;
a first wiring, provided on the gate drive circuit board, that electrically connects the voltage sensor with the second fixed part; and
a second wiring, provided on the gate drive circuit board, that electrically connects the first fixed part with the second fixed part.

2. A power converter unit according to claim 1, wherein:
the first fixed part is a screw, and the second fixed part is a first solder.

3. A power converter unit according to claim 2, wherein:
the metal plate comprises a body and a lead;
the body is a part for connecting the metal case with the screw for fixing the gate drive circuit board; and
the lead is a part for connecting the screw and the first solder.

4. A power converter unit according to claim 3, wherein:
a width of the lead is narrower than a width of the body.

5. A power converter unit according to claim 4, wherein:
the body comprises a hole.

6. A power converter unit according to claim 4, wherein:
a width of a central part of the body is narrower than a width of the part for fixing using the screw.

7. A power converter unit according to claim 5, wherein:
an end of the lead is bent in a perpendicular direction to a flat surface of the gate drive circuit board;
the gate drive circuit board comprises a through hole;
the end of the lead penetrates the through hole; and
the gate drive circuit board and the lead are fixed to each other using the first solder at the through hole.

8. A power converter unit according to claim 1, wherein:
the voltage sensor measures a voltage between the metal case and a negative electrode of a battery.

9. A power converter unit according to claim 8, wherein:
the voltage sensor is electrically connected to the negative electrode of the battery through a third wiring that is provided on the gate drive circuit board.

10. A power converter unit according to claim 2, further comprising:
the lead of the metal plate comprising a bent part; and
a second solder that fixes the lead and the gate drive circuit board, and that is different from the first solder.

11. A power converter unit according to claim 10, wherein:
the second solder is provided between the bent part of the lead and the first solder.

12. A power converter unit, comprising:
a metal case;
a power module, provided inside the metal case, that comprises a plurality of power semiconductor devices;
a gate drive circuit board, mounted on the power module, that comprises a circuit for driving the plurality of the power semiconductor devices;
a shield plate that is fixed to the metal case and placed between the power module and the gate drive circuit board;
a voltage sensor that is disposed on the gate drive circuit board;
a protrusion that is extended from the shield plate;
a first fixed part that fixes the shield plate to the gate drive circuit board;
a second fixed part that fixes the protrusion to the gate drive circuit board; and
a wiring that is provided on the gate drive circuit board to electrically connect the voltage sensor with the first fixed part.

13. A power converter unit according to claim 12, wherein:
the gate drive circuit board comprises a through hole through which the protrusion passes;
the first fixed part is a screw; and
the second fixed part is a solder that is provided at the through hole.

14. A power converter unit according to claim 13, wherein:
the shield plate and the protrusion are integrated with each other.

15. A power converter unit according to claim 13, wherein:
the voltage sensor measures a voltage between the metal case and a negative electrode of a battery.
